(19) United States
(12) Patent Application Publication
(10) Pub. No.: US 2024/0037312 A1
(43) Pub. Date: Feb. 1, 2024

(54) SELECTIVE SCAN INSERTION FOR RAPID SCAN DESIGN VERIFICATION

(71) Applicants: ATI TECHNOLOGIES ULC, MARKHAM (CA); ADVANCED MICRO DEVICES, INC., SANTA CLARA, CA (US)

(72) Inventors: David Akselrod, Hamilton (CA); Tassanee Payakapan, Toronto (CA); Arie Margulis, Markham (CA); Chad Robinson, Santa Clara, CA (US)

(21) Appl. No.: 18/087,025

(22) Filed: Dec. 22, 2022

Related U.S. Application Data
(60) Provisional application No. 63/393,344, filed on Jul. 29, 2022.

(51) Int. Cl. G06F 30/398

(52) U.S. Cl. CPC G06F 30/398

(57) ABSTRACT

Techniques for implementing selective scan insertion and verification that reduce production and verification time by enabling a test harness to insert and test scan chains are disclosed. Circuit nodes in a system model are selected and scan insertion is provided at the selected nodes. Selective scan insertion can be performed quickly and, in some implementations, automatedly to enable verification of correspondence of different system models or one or more system models and fabricated circuits. A request for manufacture may be generated including aspects of the system model to enable verification of a fabricated circuit in a similar or identical manner to those used to verify the system model.

### BACKGROUND

Integrated circuit development involves pre-manufacturing verification during which the operation of one or more portions of the integrated circuit are simulated using one or more electronic design automation (EDA) simulation tools (e.g., Verilog simulations), as well as emulated, and one or more resulting outputs are compared to a set of expected results. However, verification engineers typically must wait until a register-transfer level (RTL) description of a circuit is synthesized (e.g., to a gate-level netlist) at which stage design for verification or design for test scan chains are introduced and available as part of the electronic representation of the design to be verified (e.g., scan chains may refer to the logic used to shift a set of test patterns into a circuit and to shift out circuit responses, or test responses, of the test patterns to be compared to known good responses) for testing and verification purposes, which can cause severe delays in verifying the operation of the integrated circuit and, particularly when verification fails, can severely delay production goals, result in missed deadlines and further manufacturing delays, and otherwise negatively impact the production cycle. Often, after a problem is identified in verification, multiple design teams need to be involved in identifying and remediating the problem, which increases costs and causes further delays. Additionally, even after a problem is remediated, further verification of the entire circuit must be performed to ensure that the remediation of the identified problem does not uncover or result in other problems. Accordingly, the verification process typically consumes a large amount of time and resources, especially as integrated circuit designs become more complex and involve increasing numbers of contractors, subcontractors, and suppliers.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of a selective scan insertion system model and test harness in accordance with some implementations.

FIG. 2 is a flow diagram illustrating a method for providing selective scan insertion in accordance with some implementations.

FIG. 3 is a flow diagram illustrating a method for providing selective scan insertion and verification in accordance with some implementations.

### DETAILED DESCRIPTION

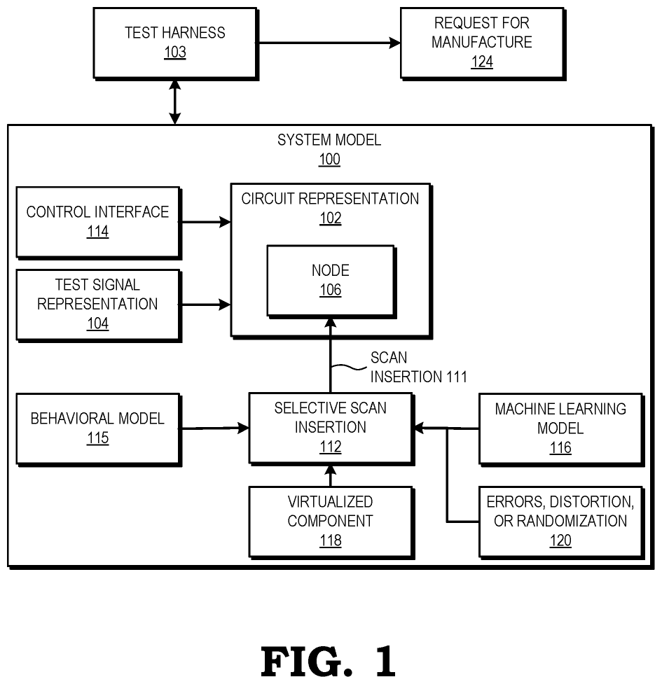

FIGS. 1-3 illustrate techniques for implementing selective scan insertion for early verification that will reduce production and verification time by enabling a test harness to selectively insert and test scan chains. Circuit nodes in a circuit representation are selected and scan insertion models are provided at the selected nodes based on user or system settings. Selective addition of logic used to shift a set of test patterns into a circuit and to shift out circuit responses, or test responses, to the test patterns, or selective addition of other elements configured to assist with verification, referred to herein as “selective scan insertion”, is performed quickly and, in some implementations, automatically to enable verification of correspondence of different circuit design or system models or one or more circuit design and system models and fabricated circuits. Although aspects of the present disclosure may add nontrivial costs to a fabricated circuit, the time and cost savings resulting from being able to perform efficient verification and troubleshooting will often outweigh the additional costs of fabrication.

To illustrate, in some implementations, circuit nodes in a circuit representation are identified as candidates for selective scan and scan insertion is performed at one or more of the nodes. In this way, a limited number of nodes are selected for scan insertion, optionally based on user preferences, such that different types of nodes, different power domains, different design parts (sometimes referred to as “tiles”), and so on, are selected for scan insertion without selecting every node in the circuit for scan insertion. Accordingly, the process of scan insertion and scan analysis is expedited. In some implementations, a request for manufacture is generated including aspects of the system model to enable verification of a fabricated circuit in a similar or identical manner to those used to verify the system model.

FIG. 1 illustrates an example of an emulation model 100 implemented in accordance with some implementations for verifying a circuit such as that stored in a circuit representation 102. In some implementations, the circuit in circuit representation 102 is stored in the form of a register-transfer level (RTL) description, which is a behavioral description of the components and connectivity of an electronic circuit. In some implementations, the circuit in circuit representation 102 is stored in the form of a netlist, which is a description of the components and connectivity of an electronic circuit using logic gates and may be produced using a synthesis tool. In order to verify the expected operation of the circuit representation 102, a test harness 103 under the control of a verification engineer simulates the application of test signals such as those stored in a test signal representation 104 to one or more nodes, or connection points, in a simulated circuit of the circuit representation 102 in the system model 100. In some implementations, nodes are located between circuit elements (e.g., between combinational logic gates, between memory modules, between different design tiles, and so on). In some implementations, the test harness 103 is a computing device or what is referred to as a verification test bench including a processor, memory, and input/output interfaces (not shown) that enable a verification engineer to interface with, test, and/or manipulate the system model 100. In some implementations, components of the test harness 103 test operation of fabricated circuits in addition to system models. Generally, the test harness 103 includes any hardware or software needed to simulate and verify a system model and/or to verify a fabricated circuit in accordance with the present disclosure.

By analyzing output data of the circuit representation 102 that is generated in response to the test signal representation 104 and often other characteristics of the performance of the circuit representation 102 the simulation provides (e.g., thermal characteristics and electromagnetic characteristics, among others), the test harness 103 determines whether the circuit representation 102 accurately performs its intended function. However, in order to verify correct operation of the circuit representation 102, the test harness 103 often needs to identify various locations in a synthesized circuit generated based on the circuit representation 102. Such a synthesized circuit is usually only available at later design stages. Thus, performing scan insertion and related verification of its functionality at those locations, simulating operation of the circuit in the circuit representation 102, and comparing the results of the simulation with results of later simulations or actual operation of a fabricated circuit based on the circuit representation 102 and the scan insertion points, would happen at later stages and, traditionally, would not be possible using an RTL-based circuit representation 102. In order to streamline scan insertion, in accordance with aspects of the present disclosure, the verification engineer and/or test harness 103 identifies one or more nodes (e.g., parts of the designs), such as the node 106 of the circuit representation 102, as candidates for selective scan insertion 112. Importantly, although examples described herein focus on the example of node 106, it will be appreciated by those skilled in the art that, in some implementations, selective scan insertion is performed at one or more power domains, design tiles, combinational logic gates, memory interfaces, flip-flops, and so on. After selecting a node such as the node 106 in the circuit representation 102, the test harness 103 uses aspects of the present disclosure in order to simulate and verify performance of the circuit representation 102.

In order to enable the test harness 103 to apply the test signal representation 104 to the circuit representation 102, in some implementations, the system model 100 includes a control interface 114 usable to provide inputs to and read outputs from a simulated circuit based on the circuit representation 102. In some implementations, the control interface 114 is external to the circuit representation 102, as shown in FIG. 1, but in other implementations the control interface 114 is wholly or partially included in the circuit representation 102. Generally, the control interface 114 enables the test harness 103 to perform scan insertion 111 at desired nodes, such as the node 106, based on selective scan insertion 112, and/or to provide inputs to or read outputs from desired nodes. Although described primarily herein as “scan insertion,” it will be appreciated by those skilled in the art that, in some implementations, the test harness 103 provides other scan-related logic or modifications to the circuit in the circuit representation 102 (i.e., other than one or more scan insertion per se). For example, rather than providing a scan insertion such as scan insertion 111, in some implementations, selective scan insertion 112 provides or instances combinational logic, RTL description, memory built-in self-test instructions or information, and/or other design for verification or design for test modules or devices (e.g., multiplexers) that the test harness 103 often interacts with by providing inputs and/or reading outputs during verification.

In some implementations, the test harness 103 selects nodes for selective scan insertion 112 based on a behavioral model 115. In some implementations, the behavioral model 115 includes statistical, heuristic, mathematical, and/or logical representations of one or more components and/or circuit representations usable by the test harness 103 to select nodes for scan insertion. For example, in some implementations, the behavioral model 115 provides the test harness 103 with a functional model of a communications interface, a memory such as a cache, a co-processor, a data bus, or a storage device, among others, such that the test harness 103 can identify nodes for scan insertion that are likely to, e.g., be interconnected with multiple devices, provide signals between different power domains, and/or produce high-power signals, among other nodes likely to be critical to performance of the circuit in the circuit representation 102. In some implementations, the test harness 103 selects the behavioral model 115 from a prepopulated library, and, in some implementations, a verification engineer configures the behavioral model 115 as needed for a specific component or specific test.

In some implementations, the test harness 103 selects nodes for selective scan insertion 112 based on a machine learning model 116. For example, in some implementations, the test harness 103 updates a machine learning support matrix using supervised or unsupervised learning in response to arbitrary outputs from the node 106, e.g., during simulated or actual operation of the circuit in circuit representation 102. In some implementations, the machine learning model 116 includes, or a verification engineer configures the machine learning model 116 as a function of, one or more artificial neural networks, decision trees, linear regressions, logistic regressions, and/or support vector machines, among others. For example, in some implementations, the machine learning model 116 identifies one or more high-power, high-traffic, high-connectivity, or highly error-prone nodes as candidates for selective scan insertion 112.

In some implementations, the test harness 103 selects nodes for selective scan insertion 112 based on a virtualized component 118. In some implementations, the virtualized component 118 includes a logical abstraction of one or more pieces of hardware or software. For example, in some implementations, the virtualized component 118 emulates an application, an operating system, a server or other computer, or a specific environment, which enables the test harness 103 to identify one or more high-power, high-traffic, high-connectivity, or highly error-prone nodes in the circuit of circuit representation 102 as candidates for selective scan insertion 112 based on analysis (e.g., monitoring operation) of the virtualized component 118 under certain conditions.

In some implementations, the test harness 103 selects nodes for scan insertion based on errors, distortion, or randomization 120 as required to ensure the robustness of the circuit of circuit representation 102. Thus, in some implementations, the test harness 103 emulates the circuit in the circuit representation 102 in order to identify potential parity errors, data distortions, and/or packet or transmission drops or errors, among others, to identify nodes for scan insertion that are likely to be associated with errors or distortions and, as a result, increase the security or reliability of a circuit of the circuit representation 102. In some implementations, the test harness 103 randomly selects nodes for scan insertion in the circuit of circuit representation 102. However, in some implementations, operation of the test harness 103 is partially or fully controllable in accordance with design preferences. For example, in some implementations, a user or design requirement specifies that random nodes should be selected for scan insertion in a circuit with an additional requirement that, e.g., at least one scan insertion is performed in each power domain, each design tile, at least one combinational logic gate, one of each of several types of combinational logic gates, and/or at least one memory module, and so on. In this way, the test harness 103 is able to perform automated selective scan insertion in an efficient, controllable manner.

Accordingly, using aspects of the present disclosure, the test harness 103 configures the control interface 114 as needed in order to perform scan insertion. By using a system model like system model 100, the test harness 103 simulates operation of elements of a circuit design with selective scan insertion 112 and verification, which enables faster, more efficient verification. After a final circuit design is complete and the test harness 103 executes all required simulations and verifies that the circuit in circuit representation 102 performs as expected, in some implementations, the verification engineer and/or test harness 103 then includes the scan insertion 111 in a request for manufacture 124. Typically, the request for manufacture 124 is a digital file or set of files that a manufacturer uses to fabricate the circuit of circuit representation 102, although the request for manufacture 124 can take any form provided that a manufacturer can use it to fabricate the desired product.

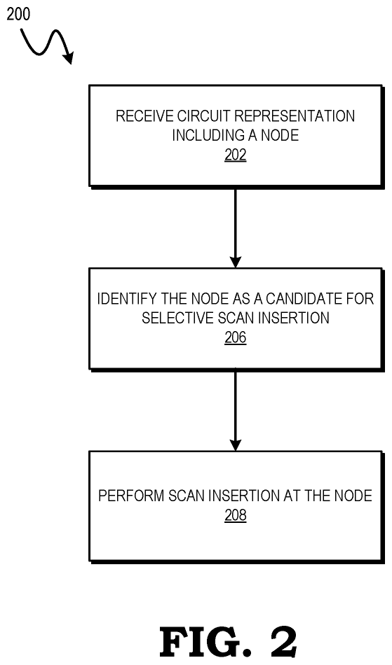

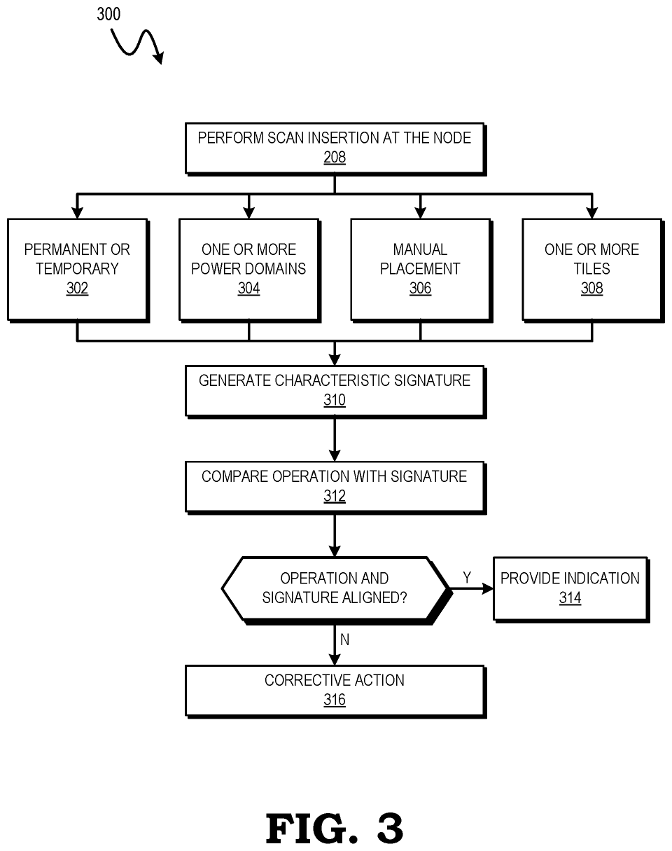

FIG. 2 is a flow diagram illustrating a method 200 for providing selective scan insertion in accordance with some implementations. As shown in FIG. 2, at block 202, a test harness like the test harness 103 of FIG. 1 receives a circuit representation such as circuit representation 102 of FIG. 1. The test harness receives the circuit representation in any appropriate manner, such as by loading a file, receiving input from a user or a design requirement, and so on. At block 206, the test harness identifies a node as a candidate for selective scan insertion. In some implementations, this identification is controllable based on user or system preferences like those described further hereinbelow in connection with FIG. 3, while in other implementations the test harness selects every node in the circuit as a candidate for selective scan insertion. At block 208, the test harness performs scan insertion at the node. In some implementations, scan insertion is controllable based on user or system preferences like those described further hereinbelow in connection with FIG. 3. In some implementations, performing scan insertion at the node includes inserting memory built-in self-test logic.

FIG. 3 is a flow diagram illustrating a method 300 for providing selective scan insertion and verification in accordance with some implementations. As shown in FIG. 3, the method 300 begins at block 208 of FIG. 2; however, in some implementations, the method 300 begins at block 206 of FIG. 2, depending on whether a user configures a test harness like the test harness 103 of FIG. 1 to only select certain nodes as candidates or to only select certain nodes for scan insertion. As will be appreciated by those skilled in the art after reading the present application in its entirety, in some implementations, a user may desire to only select certain nodes as candidates in order to expedite the process, while in other implementations a user may desire to select every node as a candidate while only selecting certain nodes for actual scan insertion, potentially enabling the user to maintain finer control over whether and how each node identified as a candidate for selective scan insertion should be selected for actual scan insertion. For example, in some implementations, a user may desire to randomly select 20 percent of all nodes in a circuit as candidate nodes, and then randomly select 10 percent of the candidate nodes for actual scan insertion. As another example, in some implementations, a user may desire to select 100 percent of the nodes in a circuit as candidate nodes, perform analysis on those nodes and, based on the analysis, select a subset of the candidate nodes for actual scan insertion. In some implementations, one or more of these requirements or conditions are specified in a design specification requirement document or pre-configured by the test harness.

As shown in FIG. 3, in order to perform scan insertion at the node at block 208, the method 300 proceeds to block 302, block 304, block 306, and/or block 308 based on user preferences or system settings. At block 302, the method 300 determines whether to use temporary or permanent scan insertions based on, e.g., whether the scan insertions are desired to be included in a fabricated circuit and/or later stages of development. At block 304, the method 300 selects one or more power domains for scan insertion based on, e.g., whether a user has indicated a minimum percent of or minimum actual number of power domains the user wishes to associate with a scan insertion. For example, a user may specify that each different power domain in a circuit must have at least one scan insertion associated therewith. As another example, a user may specify that a threshold percent or actual number of power domains must be associated with at least one scan insertion. In some implementations, these requirements or conditions are specified in a design specification requirement document or pre-configured by the test harness.

At block 306, the method 300 identifies manual placement of scan insertions by a user or software. By enabling manual placement of scan insertions, the method 300 enables a user or software to specify one or more particular nodes the user may recognize as being problematic that a test harness may not otherwise identify for scan insertion. At block 308, the method 300 identifies one or more design tiles in a circuit design a user may wish to be associated with a scan insertion. For example, in some implementations, a user may specify a threshold percent or threshold actual number of design tiles to be associated with a scan insertion such that a test harness can ensure reasonably broad distribution of scan insertions and coverage in subsequent testing.

After performing scan insertion at a node in accordance with one or more of block 302, block 304, block 306, and block 308, the method 300 proceeds to block 310, at which a test harness generates a characteristic signature for a circuit by simulating operation of the circuit and reading outputs generated at any scan insertion nodes. Once the characteristic signature is generated, the circuit can be synthesized, fabricated, or otherwise progress through the design process, and subsequent tests on the synthesized, fabricated, or otherwise different representation of the circuit are performed, e.g., by a test harness. The test harness then compares the results of these tests on the synthesized, fabricated, or otherwise different representation of the circuit with the characteristic signature at block 312 (where, e.g., the test harness is designed to monitor operation and/or outputs of a fabricated circuit) to determine whether the results of these tests are in alignment with the characteristic signature. In other words, the characteristic signature provides a “known good” representation to which other iterations of the design are compared in order to ensure a design operates as expected. If the characteristic signature matches the test results, the test harness provides a corresponding indication at block 314 (e.g., “success”). In some implementations, a fabricated circuit aligns with a characteristic signature when the outputs and/or operation of the fabricated circuit are substantially identical or equivalent to the characteristic signature.

In some implementations, if comparison with the characteristic signature fails, the method 300 may proceed to block 316, at which the test harness may perform additional scan insertions in the circuit (e.g., the circuit in circuit representation 102 of FIG. 1) and/or modify the system model and/or scan insertion operation based on the failure. For example, the test harness may place additional scan insertions at additional nodes adjacent to or within a predetermined or user-specified physical distance of nodes that produce outputs that conflict with the characteristic signature. As another example, the test harness may place additional scan insertions at nodes similar to nodes that produce outputs that conflict with the characteristic signature. Accordingly, if the output of, e.g., an adder or memory interface is found to conflict with the characteristic signature, the test harness may automatedly add additional scan insertions at other adders, other memory interfaces, or at the inputs to one or more adders or memory interfaces in order to provide a more comprehensive overview of the performance of the circuit and potential points of concern. In this way, in some implementations, the selective scan insertion is automatedly widened to enable more comprehensive review of the performance of a circuit in response to a mismatch between a characteristic signature rated based on, e.g., an RTL representation of a circuit, and testing output from, e.g., a synthesized or fabricated circuit.

In some implementations, the apparatus and techniques described above are implemented in a system including one or more integrated circuit (IC) devices (also referred to as integrated circuit packages or microchips), such as the selective scan insertion and verification described above with reference to FIGS. 1-3. Electronic design automation (EDA) and computer aided design (CAD) software tools may be used in the design and fabrication of these IC devices. These design tools typically are represented as one or more software programs. The one or more software programs include code configured to be executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any non-transitory storage medium, or combination of non-transitory storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disk, magnetic tape, or magnetic hard drive), volatile memory (e.g., random access memory (RAM) or cache), non-volatile memory (e.g., read-only memory (ROM) or Flash memory), a non-transitory computer readable medium, or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

In some implementations, certain aspects of the techniques described above may implemented by one or more processors of a processing system executing software. The software includes one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific implementations. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific implementations. However, the benefits, advantages, solutions to problems, and any feature(s) that may cause any benefit, advantage, or solution to occur or become more pronounced are not to be construed as a critical, required, or essential feature of any or all the claims. Moreover, the particular implementations disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular implementations disclosed above may be altered or modified and all such variations are considered within the scope of the disclosed subject matter.

Accordingly, the protection sought herein is as set forth in the claims below.

What is claimed is:

1. A method comprising:
receiving a circuit representation comprising a first node;
identifying the first node as a candidate for selective scan insertion; and
performing scan insertion at the first node.

2. The method of claim 1, further comprising:
simulating operation of a circuit in the circuit representation; and
in response to the simulated circuit generating an output at the first node, generating a characteristic signature for the circuit based on the output.

3. The method of claim 2, further comprising:
synthesizing or fabricating a circuit based on the circuit representation;
simulating or monitoring operation of the synthesized or fabricated circuit;
comparing the operation of the synthesized or fabricated circuit with the characteristic signature for the circuit; and
providing an indication of whether the operation of the synthesized or fabricated circuit aligns with the characteristic signature for the circuit.

4. The method of claim 3, further comprising performing scan insertion on at least one additional node in response to operation of the synthesized or fabricated circuit not aligning with the characteristic signature for the circuit.

5. The method of claim 1, wherein identifying the first node as a candidate for selective scan insertion comprises simulating operation of a virtualized component.

6. The method of claim 1, wherein identifying the first node as a candidate for selective scan insertion comprises identifying the first node based on a behavioral model or a machine learning model.

7. The method of claim 1, wherein identifying the first node as a candidate for selective scan insertion comprises monitoring the first node for errors or distortions.

8. The method of claim 1, wherein identifying the first node as a candidate for selective scan insertion comprises randomly selecting one or more nodes.

9. The method of claim 1, further comprising including the scan insertion in a request for manufacture of the circuit representation.

10. The method of claim 1, wherein performing scan insertion at the first node includes inserting memory built-in self-test logic.

11. A non-transitory computer readable medium embodying a set of executable instructions, the set of executable instructions to manipulate at least one processor to:
receive a circuit representation comprising a first node;
identify the first node as a candidate for selective scan insertion; and
perform scan insertion at the first node.

12. The non-transitory computer readable medium of claim 11, wherein the set of executable instructions is further configured to manipulate the at least one processor to:
simulate operation of a circuit in the circuit representation; and
in response to the simulated circuit generating an output at the first node, generate a characteristic signature for the circuit based on the output.

13. The non-transitory computer readable medium of claim 12, wherein the set of executable instructions is further configured to manipulate the at least one processor to:
synthesize or fabricate a circuit based on the circuit representation;
simulate or monitor operation of the synthesized or fabricated circuit;
compare the operation of the synthesized or fabricated circuit with the characteristic signature for the circuit; and
provide an indication of whether the operation of the synthesized or fabricated circuit aligns with the characteristic signature for the circuit.

14. The non-transitory computer readable medium of claim 13, wherein the set of executable instructions is further configured to manipulate the at least one processor to perform scan insertion on at least one additional node in response to operation of the synthesized or fabricated circuit not aligning with the characteristic signature for the circuit.

15. The non-transitory computer readable medium of claim 11, wherein the instructions for identifying the first node as a candidate for selective scan insertion include instructions for simulating operation of a virtualized component.

16. The non-transitory computer readable medium of claim 11, wherein the instructions for identifying the first node as a candidate for selective scan insertion include instructions for identifying the first node based on a behavioral model or a machine learning model.

17. The non-transitory computer readable medium of claim 11, wherein the instructions for identifying the first node as a candidate for selective scan insertion include instructions for monitoring the node for errors or distortions.

18. The non-transitory computer readable medium of claim 11, wherein the instructions for identifying the first node as a candidate for selective scan insertion include instructions for randomly selecting one or more nodes.

19. The non-transitory computer readable medium of claim 11, wherein the instructions for performing scan insertion at the first node include instructions for inserting memory built-in self-test logic.

20. A system model comprising:
a circuit representation comprising a node; and
selective scan insertion associated with the node of the circuit representation, wherein the selective scan insertion is configured to perform scan insertion at the node in response to identifying the node as a candidate for selective scan insertion.
